(19) United States
(12) Patent Application Publication
(10) Pub. No.: US 2015/0115936 A1
(43) Pub. Date: Apr. 30, 2015

(54) SIGNAL ERROR COMPENSATION FOR A MAGNETOMETER IN A SENSOR PACKAGE

(71) Applicant: Divya Pratap, Chandler, AZ (US)

(72) Inventor: Divya Pratap, Chandler, AZ (US)

(73) Assignee: FREESCALE SEMICONDUCTOR, INC., Austin, TX (US)

(21) Appl. No.: 14/065,059

(22) Filed: Oct. 28, 2013

(51) Int. Cl. G01R 35/00

(52) U.S. Cl. CPC G01R 35/005
USPC 324/202

(57) ABSTRACT

A device (50) includes a magnetometer (54) adapted to produce an output signal (30) indicative of a sensed magnetic field (38), a second sensor (24), and a processing unit (56) connected to each of the magnetometer and the second sensor. The processing unit is configured to perform operations that include detecting (188) whether the second sensor is in an operational state (94) in which the second sensor is drawing an electric current (82, 86), and when the second sensor is in the operational state, applying (194, 196) a trim parameter (72) to the output signal, the trim parameter canceling at least a portion of a signal error (70) on the output signal, wherein the signal error is generated at the magnetometer in response to the electric current drawn by the second sensor in the operational state.

### TECHNICAL FIELD OF THE INVENTION

The present invention relates generally to microelectromechanical systems (MEMS) sensor devices. More specifically, the present invention relates to a MEMS device package with multiple stimulus sensing capability and methodology for compensating for signal error on an output signal from a magnetometer in a multiple stimulus sensing MEMS device package.

### BACKGROUND OF THE INVENTION

Microelectromechanical systems (MEMS) technology has achieved wide popularity in recent years, as it provides a way to make very small mechanical structures and integrate these structures with electrical devices on a single substrate using conventional batch semiconductor processing techniques. One common application of MEMS is the design and manufacture of sensor devices. MEMS sensor devices include, for example, accelerometers, gyroscopes, pressure sensors, magnetic field sensors, microphones, gas sensors, digital mirror displays, micro fluidic devices, and so forth. MEMS sensor devices are widely used in applications such as automotive, inertial guidance systems, household appliances, game devices, protection systems for a variety of devices, and many other industrial, scientific, and engineering systems.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, the Figures are not necessarily drawn to scale, and:

FIG. 1 shows a block diagram of a microelectromechanical systems (MEMS) device package having multiple stimulus sensing capability;

FIG. 2 shows a block diagram of another microelectromechanical systems (MEMS) device package having multiple stimulus sensing capability;

FIG. 3 shows a conceptual block diagram of a multiple stimulus sensing MEMS device package in accordance with an embodiment;

FIG. 4 shows an exemplary state diagram demonstrating operational states of sensors within the MEMS device package of FIG. 3;

FIG. 5 shows a test environment for determining trim parameters for the MEMS device package of FIG. 3;

FIG. 6 shows a flowchart of a gyroscope-based offset trim value determination process;

FIG. 7 shows a flowchart of a sensitivity shift value determination process;

FIG. 8 shows a flowchart of a real-time calculation subprocess of the sensitivity shift value determination process; and

FIG. 9 shows a flowchart of a magnetometer signal error compensation process in accordance with an embodiment.

### DETAILED DESCRIPTION

As the uses for MEMS devices continue to grow and diversify, increasing emphasis is being placed on the development of devices capable of multiple stimulus sensing at enhanced sensitivities and for integrating multiple types of sensors into the same package. A multiple stimulus sensing MEMS device package, sometimes referred to as a “combination sensor” or simply a “combo sensor” may be capable of sensing different physical stimuli (e.g., linear acceleration, angular rate, magnetic fields, pressure, and so forth) and may be further capable of multiple axis sensing. In addition, increasing emphasis is being placed on fabrication methodology for MEMS device packages having multiple physical stimuli sensing and/or multiple axis sensing capability without increasing manufacturing cost and complexity and without sacrificing part performance. These efforts are primarily driven by existing and potential high-volume applications in automotive, medical, commercial, and consumer products.

Some applications call for a multiple stimulus sensing MEMS device package that includes both a magnetometer and a gyroscope. In general, a magnetometer, also referred to as a magnetic field sensor, is an electronic device for detecting the magnitude and/or orientation of a magnetic field. A gyroscope broadly functions by driving the gyroscope into a first motion and measuring a second motion of the gyroscope that is responsive to both the first motion and the angular velocity to be sensed. In a MEMS device package that includes a magnetometer and a gyroscope, during certain operational states, the gyroscope will draw current. The current draw generates a magnetic field, which may be detected at the magnetometer. Accordingly, the magnetic field generated in response to current draw by the gyroscope can impose signal error on the output signal of the magnetometer.

Embodiments entail a multiple stimulus sensing MEMS device package that includes both a magnetometer and another sensor, such as a gyroscope, and methodology for compensating for signal error imposed on the magnetometer output signal when the other sensor is in an operational state. The methodology is implemented in an analog front end and digital processing application specific integrated circuit (ASIC) of the magnetometer to improve signal accuracy, to reduce memory requirements, and to provide an error compensated signal to an end user without the need for implementation of end user logic.

Although embodiments herein are described in connection with a gyroscope as the source of signal error on the magnetometer output signal, it should be understood that the methodology for compensating for signal error on the magnetometer output signal may be implemented in other multiple stimulus sensing MEMS device packages in which another sensor draws current that produces a magnetic field, which may subsequently be imposed on the magnetometer output signal as an error signal, and for which compensation for such an error signal is needed.

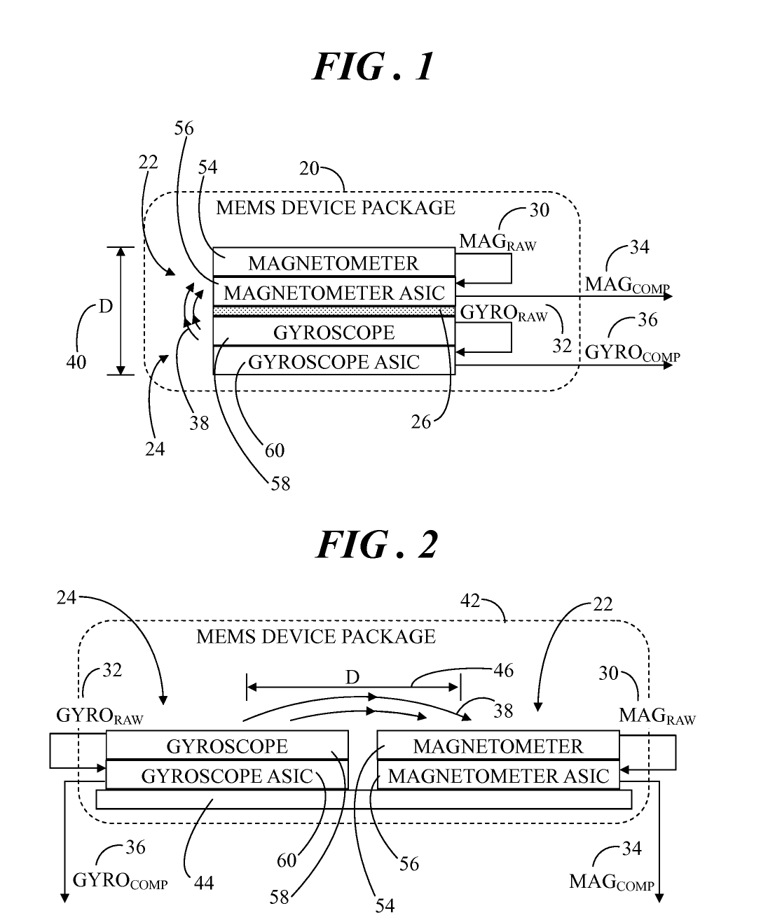

FIG. 1 shows a block diagram of a multiple stimulus sensing MEMS device package 20. MEMS device package 20 generally includes a magnetometer die 22 and a gyroscope die 24 in a stacked configuration in which a die attach material 26 is used to couple, or fasten, magnetometer die 22 and gyroscope die 24 together. Magnetometer die 22 can include one or more magnetic field sense elements 54 and a magnetometer circuit 56. Similarly, gyroscope die 24 can include one or more gyroscope sense element 58 and a gyroscope circuit 60. Magnetometer circuit 56 and magnetic field sense element 54 are provided in a stacked configuration in magnetometer die 22. However, in alternative embodiments, magnetometer circuit 56 may be laterally displaced from magnetic field sense element 54. Likewise, gyroscope circuit 60 and gyroscope sense element 58 are provided in a stacked configuration in gyroscope die 24. However, in alternative embodiments, gyroscope circuit 60 may be laterally displaced from gyroscope sense element 58.

Magnetometer circuit 56 may be an application specific integrated circuit (ASIC) analog front end and digital block within magnetometer die 22 at which compensation algorithms may be executed and trim parameters may be stored. Likewise, gyroscope die 24 may be an ASIC analog front end and digital block within gyroscope die 24 at which compensation algorithms may be executed. In general, magnetometer circuit 56 is configured to receive a raw, i.e., analog, output signal, referred to herein as a magnetometer output signal 30, labeled MAG_{RAW}, from magnetic field sense element 54. Similarly, gyroscope circuit 60 is configured to receive a raw, i.e., analog, output signal, referred to herein as a gyroscope output signal 32, labeled GYRO_{RAW}, from gyroscope sense element 58.

In response to receipt of magnetometer output signal 30 and gyroscope output signal 32, magnetometer circuit 56 and gyroscope circuit 60 execute compensation algorithms to remove signal error components and therefore improve the performance of magnetometer and gyroscope output signals 30, 32. Fixed compensation coefficients can correct for temperature offset, temperature sensitivity, and other factors that might otherwise adversely affect the performance of magnetometer die 22 and gyroscope die 24. In addition to error compensation, magnetometer and gyroscope circuits 56, 60 may perform certain processing operations to convert the raw analog magnetometer output signal 30 and the raw analog gyroscope output signal 32 to digital form in accordance with known methodologies. Thus, magnetometer circuit 56 will output a compensated, digital output signal, referred to herein as a compensated magnetometer output signal 34, labeled MAG_{COMP}, corresponding to raw magnetometer output signal 30. Additionally, gyroscope circuit 60 will output a compensated, digital output signal, referred to herein as a compensated gyroscope output signal 36, labeled GYRO_{COMP}.

In MEMS device package 20, under certain operational states, gyroscope die 24, and more particularly, gyroscope circuit 60, draws electric current. The current draw can be substantially constant, which may also be referred to as substantially non-variable, when gyroscope die 24 is in a standby state. A standby state may be one in which only essential components of gyroscope die 24 are energized. Thus, the current draw by gyroscope die 24 may be relatively low and non-variable. Alternatively, the current draw may be changing, i.e., variable, in which additional components of gyroscope die 24 are selectively energized, and gyroscope die 24 may be subjected to angular velocity. In either instance, the current draw generates a magnetic field, illustrated by curved lines 38 in FIG. 1, which may be detected at magnetic field sense element 54 of magnetometer die 22. Accordingly, magnetic field 38 generated in response to current draw by gyroscope die 24 can impose signal error on magnetometer output signal 30. The signal error is a function of both the magnitude and variability of the current draw, as well as a distance 40, labeled D in FIG. 1, between magnetic field sense element 54 and gyroscope circuit 60. This signal error can be characterized by Ampere's law in which the magnetic field in space around an electric current is proportional to the electric current which serves as its source. The signal error can thus be represented by the following equation:

B=u₀*uᵣ*I(2πr)

where B is the signal error, u₀ and uᵣ are fixed coefficients, I is the current, and r is distance 40. In accordance with an embodiment, a compensation algorithm is implemented within magnetometer circuit 56, and in particular, as an adjunct to an existing compensation algorithm, to compensate for the signal error on magnetometer output signal 30 from magnetic field 38 produced by gyroscope die 24, when gyroscope die 24 is in an operational state.

FIG. 2 shows a block diagram of another multiple stimulus sensing MEMS device package 42. Like MEMS device package 20, MEMS device package 42 also includes magnetometer die 22, gyroscope die 24, in which magnetometer die 22 produces magnetometer output signal 30, gyroscope die 24 produces gyroscope output signal 32, magnetometer circuit 56 produces compensated magnetometer output signal 34, and gyroscope circuit 60 produces compensated gyroscope output signal 36.

In the configuration shown in FIG. 2, however, magnetometer die 22 and gyroscope die 24 are not in the stacked arrangement of FIG. 1. Instead, magnetometer die 22 and gyroscope die 24 are each mounted on a substrate 44 at locations that are laterally displaced from one another by a distance 46, labeled D. Nevertheless, gyroscope circuit 60 of gyroscope die 24 still produces magnetic field 38 when it's in an operational state, and this magnetic field 38 may still be detectable at magnetic field sense element 54 of magnetometer die 22 as signal error on magnetometer output signal 30. Accordingly, the compensation algorithm can also be implemented within MEMS sensor device 42 to compensate for the signal error on magnetometer output signal 30 from magnetic field 38 produced by gyroscope die 24.

It should become readily apparent that the compensation methodology for compensating for the signal error on magnetometer output signal 30 may be implemented in a wide variety of multiple stimulus sensing MEMS device packages having various structural configurations. Furthermore, the compensation methodology can be implemented in multiple axis sensing configurations.

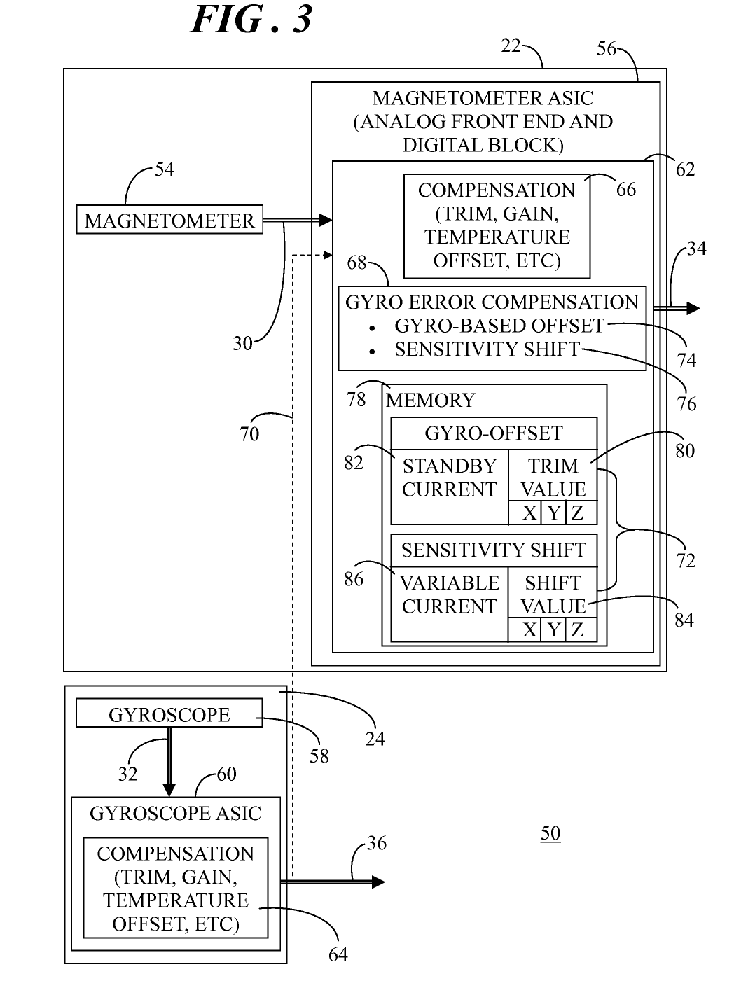

FIG. 3 shows a conceptual block diagram of a multiple stimulus sensing MEMS device package 50 in accordance with an embodiment. MEMS device package 50 may be either of packages 20 of FIG. 1 or 42 of FIG. 2. Alternatively, MEMS device package 50 may be any multiple stimulus sensing MEMS device package that includes at least one single or multiple axis magnetometer as well as another sensor that draws current under certain circumstances, and that is in close proximity to the magnetometer such that an error signal may be imposed on the magnetometer output signal in response to a magnetic field produced by the electric current drawn by the other sensor.

For purposes of illustration, MEMS device package 50 includes both magnetometer die 22 and gyroscope die 24. Of course, MEMS device package 50 may additionally include other sensors and MEMS components not described or illustrated herein for simplicity. As mentioned above, magnetometer die 22 includes one or more sense elements 54, capable of sensing a magnetic field along one or more axes, and associated magnetometer circuit 56. Similarly, as mentioned above, gyroscope die 24 includes one or more sense elements 58, capable of sensing angular rate about one or more axes, and associated gyroscope circuit 60. Magnetometer die 22 and gyroscope die 24 can be any of a variety of single axis and multiple axis structural designs.

Magnetometer circuit 56 may include a processing section 62 for receiving magnetometer output signal 30 from magnetic field sense element 54 of magnetometer die 22 and producing compensated magnetometer output signal 34. Gyroscope circuit 60 may include a processing section 64 for receiving gyroscope output signal 32 from gyroscope sense element 58 of gyroscope die 24 and producing compensated gyroscope output signal 36. Processing section 64 may perform compensation on gyroscope output signal 36, in the form of trim adjust, gain, temperature offset correction, and so forth in accordance with known methodologies.

Processing section 62 may include a compensation algorithm 66 for performing conventional compensation on magnetometer output signal 30, such as, trim offset, gain adjust, temperature offset, temperature sensitivity, and so forth. In accordance with an embodiment, processing section 62 further includes another compensation algorithm 68 for compensating for signal error, represented by a dashed line 70, imposed on magnetometer output signal 30 when gyroscope die 24 is in an operational state.

In an embodiment, compensation algorithms 66 and 68 are implemented as logic gates on the silicon of MEMS device package 50. Compensation algorithm 66 refers to a “regular” or conventional compensation algorithm for calibrating or otherwise trimming magnetometer output signal 30. Compensation algorithm 68 refers to an algorithm in accordance with an embodiment for compensating for, i.e., cancelling at least a portion of, signal error 70 imposed on magnetometer output signal 30 when gyroscope die 24 is in an operational state. Thus, algorithms 66 and 68 are shown as separate elements for exemplary purposes. In actual practice, compensation algorithm 68 is implemented as an adjunct to conventional compensation algorithm 66 when magnetometer die 22 within a multiple stimulus sensing MEMS device package, such as device package 50, is subjected to signal error 70 produced by current from another sensor device, e.g., gyroscope die 24.

Through the execution of a compensation algorithm 68, trim parameters 72 may be selectively applied to magnetometer output signal 30 to compensate for signal error 70 resulting from current draw by gyroscope die 24. This signal error 70 could include a gyroscope-based offset component 74 and/or a sensitivity shift component 76. In general, gyroscope-based offset component 74 can occur under conditions where there is non-variable, i.e., a constant current draw, by gyroscope die 24, which causes a change in magnetometer output signal 30 due to the imposition of error signal 70. Sensitivity shift component 76 can occur under conditions where there is active current change, i.e., variable current, produced by gyroscope die 24 due to load capacitance on gyroscope die 24. Sensitivity shift component 76 can also occur if the electric current from gyroscope 24 increases linearly or decreases linearly.

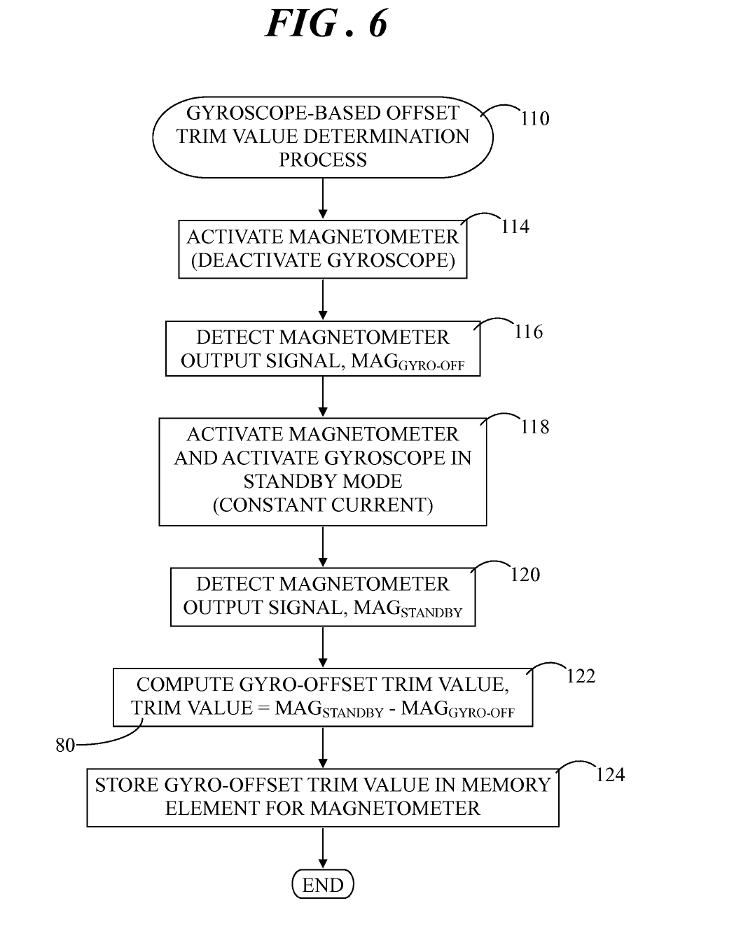

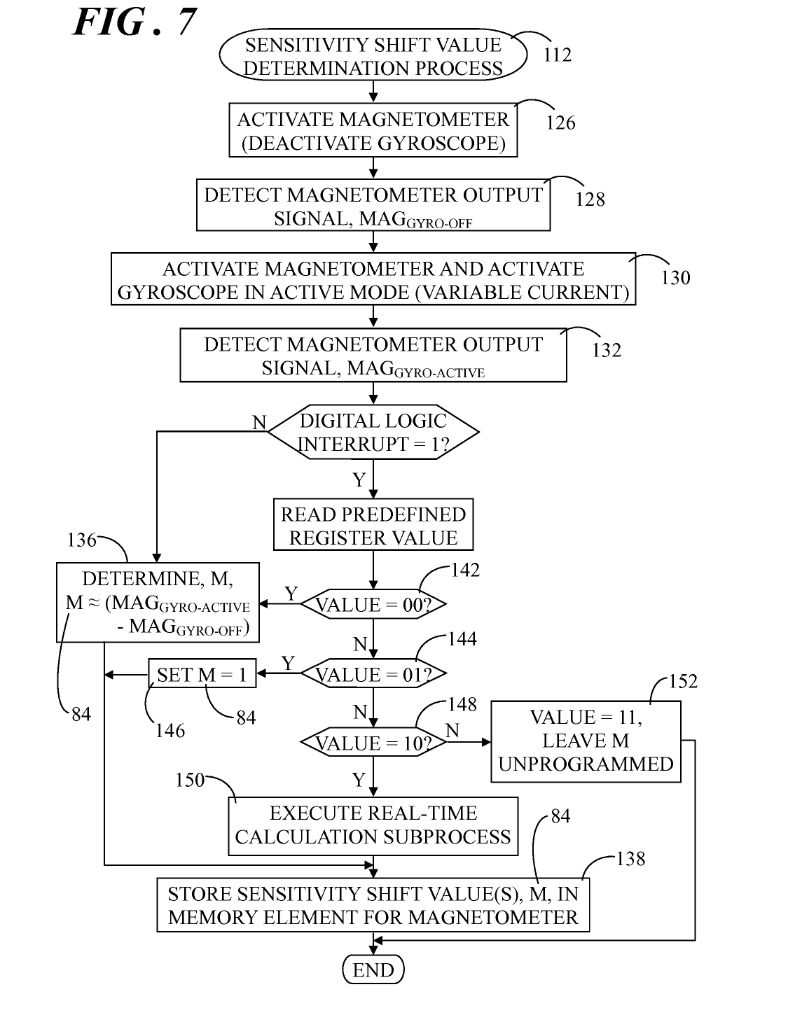

In an embodiment, trim parameters 72 can be determined during device testing (discussed in connection with FIG. 5). Trim parameters 72 can subsequently be stored in a memory element 78 associated with compensation algorithm 68. Trim parameters 72 can include one or more gyroscope-based offset trim values 80 associated with a non-variable standby current 82 for gyroscope die 24. Gyroscope-based offset trim value 80 may be used to compensate for gyroscope-based offset component 74 of signal error 70. The determination of gyroscope-based offset trim value 80 will be discussed in connection with FIG. 6. Additionally, or alternatively, trim parameters 72 can include one or more sensitivity shift values 84 associated with a variable current 86 for gyroscope die 24. Sensitivity shift value 84 may be used to compensate for sensitivity shift component 76 of signal error 70. The determination of sensitivity shift value 84 will be discussed in connection with FIG. 7.

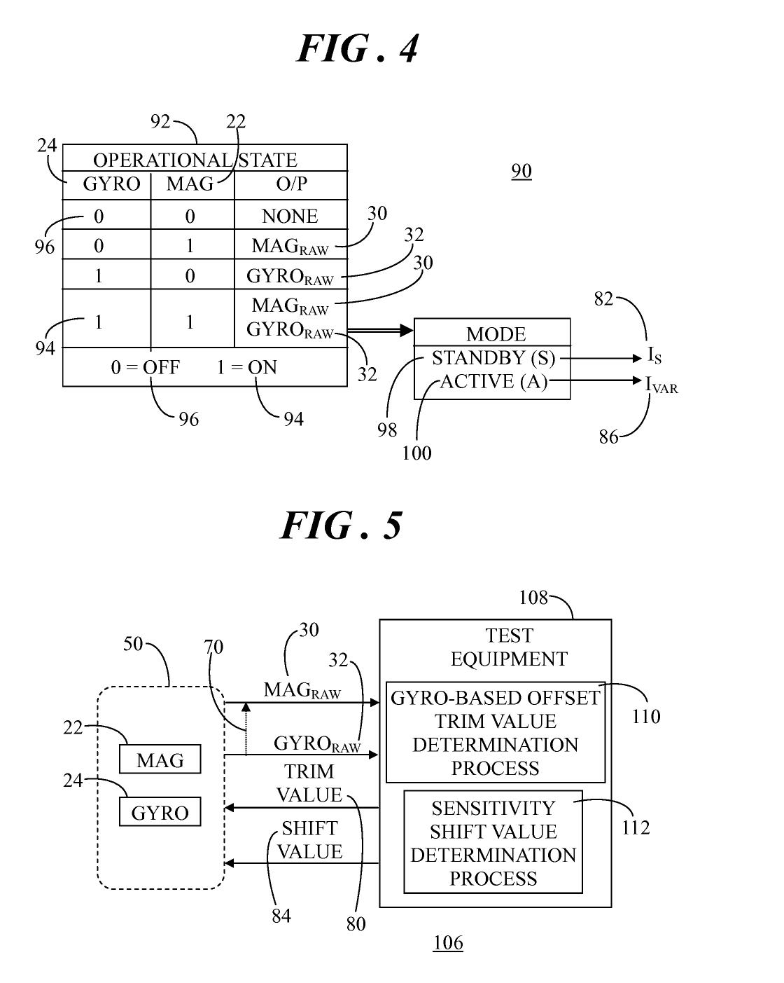

FIG. 4 shows an exemplary state diagram 90 demonstrating multiple operational states 92 of sensors 22, 24 within MEMS device package 50 of FIG. 3. As shown in state diagram 90, at any instant each of magnetometer die 22 and gyroscope die 24 may be in one of an operational state 94 or a non-operational state 96. Operational state 94 is represented by the numeral “1” and non-operational state 96 is represented by the numeral “0.”

State diagram 90 also shows which of magnetometer die 22 and gyroscope die 24 are enabled to produce an output signal (O/P) in accordance with its particular operational state. By way of example, when both gyroscope die 24 and magnetometer die 22 are in non-operational state 96 (i.e., “0” and “0” in state diagram 90), neither gyroscope die 24 nor magnetometer die 22 are enabled to produce their respective gyroscope and magnetometer output signals 32 and 30. When gyroscope die 24 is in non-operational state 96 and magnetometer die 22 is in operational state 94 (i.e., “0” and “1” in state diagram 90), only magnetometer die 22 is enabled to produce magnetometer output signal 30. Similarly, when gyroscope die 24 is in operational state 94 and magnetometer die 22 is in non-operational state 96 (i.e., “1” and “0” in state diagram 90), only gyroscope die 24 is enabled to produce gyroscope output signal 32.

Of particular interest herein, when both gyroscope die 24 and magnetometer die 22 are in operational state 94 (i.e., “1” and “1” in state diagram 90), both gyroscope die 24 and magnetometer die 22 are enabled to produce their respective gyroscope and magnetometer output signals 32 and 30. Thus, it is in this dual operational state 94 in which signal error 70 of FIG. 3 can be imposed on magnetometer output signal 30.

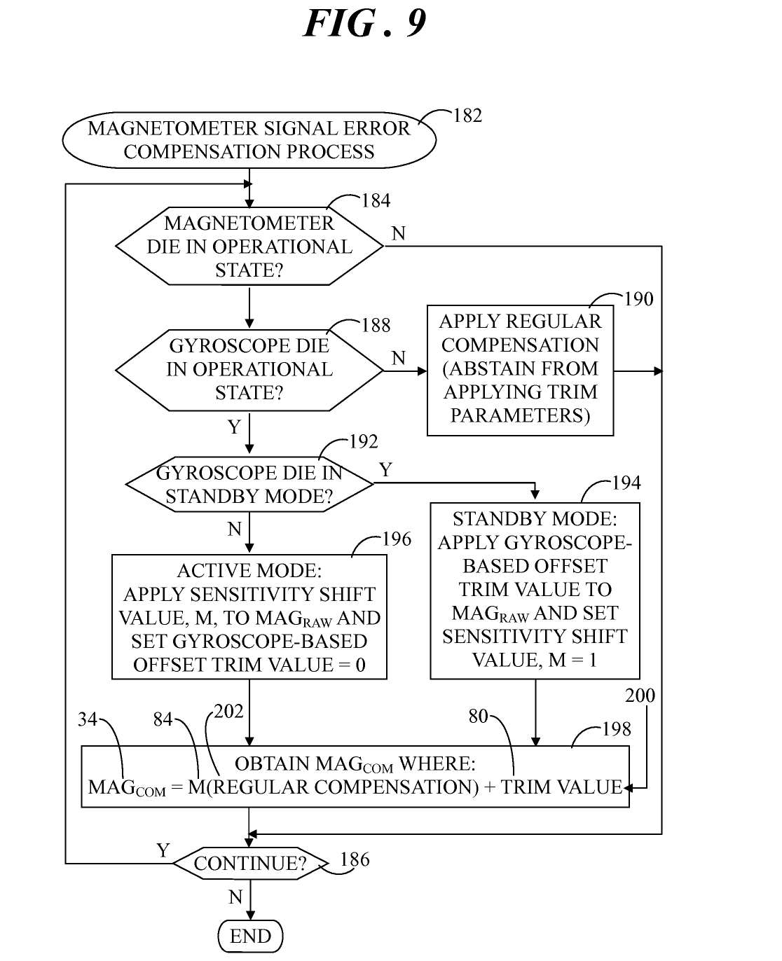

Operational state 94 for gyroscope die 24 may be one of two modes, i.e., a standby mode 98 and an active mode 100. In standby mode 98, gyroscope die 24 is activated/operational. However, gyroscope die 24 is drawing a constant electric current, and more particularly non-variable standby current 82, labeled I_{S} in FIG. 4. Conversely, in active mode 100, gyroscope is activated/operational. However, gyroscope die 24 is drawing a non-constant electric current, and more particularly, variable electric current 86, labeled I_{VAR} in FIG. 4. Thus, for purposes of the following description, gyroscope die 24 can be in 1) operational state 94, standby mode 98, 2) operational state 94, active mode 100, or 3) non-operational state 96. Compensation methodology discussed in connection with FIG. 9 compensates for signal error 70 of FIG. 3 based upon the current operational state and mode of gyroscope die 24.

FIG. 5 shows a test environment 106 for determining trim parameters 72 of FIG. 3 for MEMS device package 50 of FIG. 3. In general, the electro-mechanical characteristics of each MEMS device, such as MEMS device package 50, may differ due to a variety of factors (manufacturing tolerances, slight differences in processing, temperature offset, temperature sensitivity, and so forth). This means that the electrical output of one MEMS device responsive to a certain magnitude of stimulus might be different from the electrical output of a second MEMS device responsive to a stimulus of the very same magnitude. Of course, it is important that MEMS devices be calibrated such that a system can correlate a given electrical output from the MEMS sensor to a specific amount of applied stimulus. Typically this calibration/compensation occurs prior to shipment of the system employing the MEMS sensor, and may be accomplished by applying the actual physical stimulus (for example, a magnetic field or an angular rate) to the system, measuring the electrical response of the MEMS sensor, and storing values in the system representative of any “correction” factors that need to be applied to the electrical output of the MEMS sensor to make sure that the “corrected” MEMS sensor output corresponds to the magnitude of the applied stimulus.

Accordingly, MEMS device package 50 may be coupled to test equipment 108 to compute, for example, sensitivity parameters, temperature offset parameters, temperature sensitivity parameters, and so forth in accordance with conventional compensation algorithm 66. In an embodiment, MEMS device package 50 may be coupled to test equipment 108 to compute trim parameters 72, more specifically, to determine gyroscope-based offset trim value 80 of FIG. 3 and/or sensitivity shift value 84 of FIG. 3, in accordance with compensation algorithm 68 of FIG. 3.

In test environment 106, test equipment 108 may be suitably coupled with MEMS device package 50 so that MEMS device package 50 outputs raw magnetometer output signal 30 and raw gyroscope output signal 32 to test equipment 108. In an embodiment, test equipment 108 executes a gyroscope-based offset trim value determination process 110 and provides one or more gyroscope-based offset trim values 80 to MEMS device package 50 for storage in memory element 78 of FIG. 3. Test equipment 108 may additionally execute a sensitivity shift value determination process 112, and provide one or more sensitivity shift values 84 to MEMS device package 50 for storage in memory element 78.

Test environment 106 may be “factory-based” and testing may take place prior to MEMS device package 50 being board mounted. For example, MEMS device package 50 may be coupled within conventional sockets (not shown) of test equipment 108 to perform testing on MEMS device package 50 prior to package being board mounted within a customer application. Alternatively, test environment 106 may be “customer-based” and testing may take place after MEMS device package 50 has been board mounted in a customer application. As will be discussed in greater detail below, sensitivity shift of magnetometer die 22 can occur as a result of sensitivity shift component 76 of FIG. 3 of signal error 70 resulting from gyroscope die 24. Additionally, sensitivity shift can also result after MEMS device package 50 has been board mounted in a customer application. Thus, stress on magnetometer die 22 could potentially change the performance of magnetic field sense element 54 of FIG. 3 of magnetometer die 22.

Sensitivity shift value determination process 112 may be performed prior to board mount when test environment 106 is factory-based so that one or more sensitivity shift values 84 determined through the execution of process 112 are governed by the performance of gyroscope die 24. Alternatively, or additionally, sensitivity shift value determination process 112 may be adapted for execution following board mount in a customer-based test environment 106 so that the one or more sensitivity shift values 84 determined through the execution of process 112 are governed both by the performance of gyroscope die 24 and by the stress conditions imposed on magnetometer die 22 within the customer application. Those skilled in the art will recognize that sensitivity shift may occur due to other factors that are not discussed herein for brevity.

Referring now to FIGS. 5 and 6, FIG. 6 shows a flowchart of a gyroscope-based offset trim value determination process 110 performed during testing of MEMS device package 50 of FIG. 3 using test equipment 108 within test environment 106. Process 110, executed by test equipment 108, is provided herein for illustrative purposes. However, it is to be understood that certain ones of the process blocks depicted in FIG. 6 may be performed in parallel with each other or with performing other processes. In addition, it is to be understood that the particular ordering of the process blocks depicted in FIG. 6 may be modified, while achieving substantially the same result. Accordingly, such modifications are intended to be included within the scope of the inventive subject matter.

In general, the term “offset” applies to a displacement from an expected output signal. In particular, the term “gyroscope-based offset” refers to the displacement from an expected magnetometer output signal due to signal error 70. Thus, gyroscope-based offset trim value determination process 110 is performed to determine gyroscope-based offset value 80 to thereby compensate for gyroscope-based offset component 74 of FIG. 3 of signal error 70 in order to correct for this displacement.

Trim value determination process 110 begins with a task 114. At task 114, magnetometer die 22 is activated, i.e., placed in operational state 94, and gyroscope die 24 is deactivated, i.e., placed in non-operational state 96 (0-1 in state diagram 90 shown in FIG. 4).

A task 116 is performed in connection with task 114. At task 116, magnetometer output signal 30 from magnetometer die 22 is detected at test equipment 108. As shown in task block 116, magnetometer output signal 30 is referred to as MAG_{GYRO-OFF} to emphasize that gyroscope die 24 is in non-operational state 96. Accordingly, magnetometer output signal 30 will not have signal error 70 imposed on it.

Process 110 continues with a task 118. At task 118, magnetometer die 22 is again activated, i.e., placed in operational state 94, and gyroscope die 24 is also activated, i.e., placed in operational state 94 (1-1 in state diagram 90 shown in FIG. 4). Additionally, gyroscope die 24 is placed in standby mode 98 of FIG. 4 such that gyroscope die 24 draws non-variable electric standby current 82 of FIG. 3. Under these conditions, standby current 82 produces magnetic field 38 of FIG. 1 which may be imposed on magnetometer output signal 30.

Accordingly, a task 120 is performed in connection with task 118. At task 120, magnetometer output signal 30 is again detected at test equipment 108. However, magnetometer output signal 30 may include signal error 70 resulting from magnetic field 38, in the form of gyroscope-based offset component 74 of FIG. 3. Accordingly, as shown in task block 120, magnetometer output signal 30 is referred to as MAG_{STANDBY} to emphasize that gyroscope die 24 is in operational state 94 of FIG. 4, but in standby mode 98 of FIG. 4.

Trim value determination process 110 continues with a task 122. At task 122, gyroscope-based offset trim value 80 is generally computed as the difference between the magnetometer output signals 30, i.e., MAG_{STANDBY} minus MAG_{GYRO-OFF}.

Following task 122, process 110 continues with a task 124. At task 124, gyroscope-based offset trim value 80 is stored in memory element 78 of FIG. 3 for implementation within gyro error compensation algorithm 68. In some embodiments, gyroscope-based offset trim value 80 may be stored in association with non-variable standby current 82. Trim value determination process 110 ends following task 124.

The above presented trim value determination process 110 provides a description for determining trim value 80 for a single detection axis of magnetometer die 22. In some embodiments, magnetometer die 22 may be capable of sensing magnetic fields along more than one axis, and outputting corresponding magnetometer output signals for each axis. With such a configuration, detection tasks 116 and 120 may be performed for each sense axis of magnetometer die in order to compute multiple gyroscope-based offset trim values 80, where each trim value 80 is associated with its particular sense axis for magnetometer die 22. Accordingly, trim parameters 72 of FIG. 3 for gyroscope-based offset component 74 may include multiple gyroscope-based offset trim values 80 (represented by X, Y, Z in FIG. 3).

Referring now to FIGS. 5 and 7, FIG. 7 shows a flowchart of sensitivity shift value determination process 112 performed during testing of MEMS device package 50 of FIG. 3 using test equipment 108 within test environment 106. Process 112, executed by test equipment 108, is provided herein for illustrative purposes. However, it is to be understood that certain ones of the process blocks depicted in FIG. 7 may be performed in parallel with each other or with performing other processes. In addition, it is to be understood that the particular ordering of the process blocks depicted in FIG. 7 may be modified, while achieving substantially the same result. Accordingly, such modifications are intended to be included within the scope of the inventive subject matter. Furthermore, gyroscope-based offset trim value determination process 110 of FIG. 6 and sensitivity shift value determination process 112 are described separately for clarity. However, it should be understood that the two processes 110 and 112, have some common operations and may therefore be combined into a single process.

In general, the term “sensitivity” refers to the change in magnetometer output signal 30 in response to the change in magnetic field detectable by magnetometer die 22. This change in magnetic field should be within a predefined specification. If the change in magnetic field is greater than or less than the predefined specification, this is referred to as sensitivity shift 76. In some instances, magnetic field 38 generated in response to variable electric current 84 can cause a change in the detected magnetic field, i.e., magnetometer output signal 30, that is outside of the predefined specification. Thus, sensitivity shift value determination process 112 is performed to determine sensitivity shift value 84 to thereby compensate for the sensitivity shift component 76 of FIG. 3 of signal error 70 so that compensated magnetometer output signal 34 of FIG. 3 falls within the predefined specification.

In an embodiment, sensitivity shift value determination process 112 is executed during “factory testing” of MEMS device package 50 prior to board mount of package 50 is a customer application. Accordingly, the determined sensitivity shift value 84 is governed by performance of, i.e., current draw, of gyroscope die 24. However, as mentioned above, sensitivity shift can also occur due to the stress imposed on magnetometer die 22 following board mount. Accordingly, in some embodiments, sensitivity shift value determination process 112 may be adapted for use following board mount of MEMS device package 50 so that the determined sensitivity shift value 84 is governed by both the performance of gyroscope die 24 as well as stress conditions imposed on magnetometer die 22.

Sensitivity shift value determination process 112 begins with a task 126. At task 126, magnetometer die 22 is activated, i.e., placed in operational state 94, and gyroscope die 24 is deactivated, i.e., placed in non-operational state 96 (0-1 in state diagram 90 shown in FIG. 4).

A task 128 is performed in connection with task 126. At task 128, magnetometer output signal 30 from magnetometer die 22 is detected at test equipment 108. As shown in task block 128, magnetometer output signal 30 is referred to as MAG_{GYRO-OFF} to emphasize that gyroscope die 24 is in non-operational state 96. Accordingly, magnetometer output signal 30 will not have signal error 70 imposed on it.

Process 112 continues with a task 130. At task 130, magnetometer die 22 is again activated, i.e., placed in operational state 94, and gyroscope die 24 is also activated, i.e., placed in operational state 94 (1-1 in state diagram 90 shown in FIG. 4). Additionally, gyroscope die 24 is placed in active mode 100 of FIG. 4 such that gyroscope die 24 draws variable electric current 84. Under these conditions, variable electric current 84 produces magnetic field 38 of FIG. 1 which may be imposed on magnetometer output signal 30.

Accordingly, a task 132 is performed in connection with task 130. At task 132, magnetometer output signal 30 is again detected at test equipment 108. However, magnetometer output signal 30 may include signal error 70 caused by magnetic field 38, in the form of sensitivity shift component 76 of FIG. 3. Sensitivity shift component 76 may be responsive to the variability of, or change in, variable current 84 when gyroscope die 24 is in active mode 100 of FIG. 4. Accordingly, as shown in task block 132, magnetometer output signal 30 is referred to as MAG_{GYRO-ACTIVE} to emphasize that gyroscope die 24 is in operational state 94 of FIG. 4, and particularly in active mode 100.

Sensitivity shift value determination process 112 continues with a query task 134. At query task 134, a determination is made as to whether a digital logic interrupt signal is set to one. In some embodiments, the digital logic interrupt signal would come from magnetometer circuit 56 of FIG. 3. A digital logic interrupt signal may be implemented in order to continuously monitor a change in magnetometer output signal 30. The continuous monitoring enables sensitivity shift value 84, M, to be changed in real-time so that sensitivity shift value 84 can change as variable current 86 of FIG. 3 changes in a customer application. At query task 134, when a determination is made that the digital logic interrupt signal is not set to one, i.e., digital logic signal equals zero, process 112 continues with a task 136.

At task 136, sensitivity shift value 84, M, is generally computed in response to the difference between the magnetometer output signals 30, i.e., MAG_{GYRO-ACTIVE} and MAG_{GYRO-OFF}. Thus, sensitivity shift value 84, M, is characterized in response to magnetometer output signals 30.

Following task 136, program control proceeds to a task 138. At task 138, sensitivity shift value 84, M, is stored in memory element 78 of FIG. 3 for implementation within gyro error compensation algorithm 68. In some embodiments, sensitivity shift value 84, M, may be stored in association with variable electric current 86. Sensitivity shift value determination process 112 ends following task 138.

Now returning to query task 134, when a determination is made that the digital logic interrupt is set to one, process 112 continues with a task 140. At task 140, a predefined register value is read from, for example, magnetometer circuit 60 of FIG. 3. In an embodiment, this predetermined register value may be “00,” “01,” “10,” or “11.” The predetermined register value may be implemented to determine how sensitivity shift value 84, M, should be programmed for MEMS device package 50. Alternative embodiments may include less than or more than the four variations for determining how sensitivity shift value 84 may be programmed, as described below.

In response to task 140, a query task 142 determines whether the predetermined register value is equal to “00.” When the predetermined register value is equal to “00,” process control proceeds to task 136 to compute sensitivity shift value 84, M, in response to the difference between the magnetometer output signals 30, i.e., MAG_{GYRO-ACTIVE} and MAG_{GYRO-OFF}. This sensitivity shift value 84 can be stored in memory element 78 of FIG. 3 at task 138 as described above. However, when query task 142 determines that the predetermined register value is not equal to “00,” process 112 continues with a query task 144.

Query task 144 determines whether the predetermined register value is equal to “01.” When the predetermined register value is equal to “01,” process control proceeds to a task 146. At task 146, sensitivity shift value 84, M, is set to one. Following task 146, process 112 continues with task 138 so that the sensitivity shift value 84 of one is stored in memory element 78. Thus, in this configuration, MEMS device package 50 will not include a compensation feature for sensitivity shift component 76 of FIG. 3 of signal error 70. However, when query task 144 determines that the predetermined register value is not equal to “01,” process 112 continues with a query task 148.

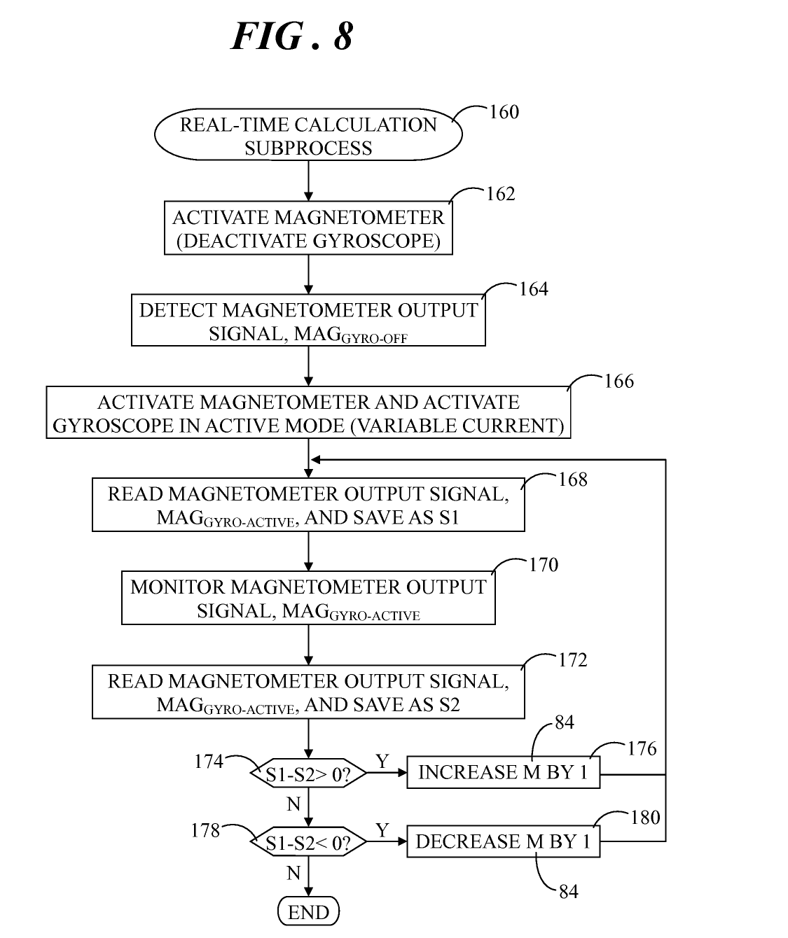

Query task 148 determines whether the predetermined register value is equal to “10.” When the predetermined register value is equal to “10,” process control proceeds to a task 150. At task 150, a real-time calculation subprocess is executed to determine sensitivity shift value 84. An exemplary real-time calculation subprocess will be described below in connection with FIG. 8. However, following execution of the real-time calculation subprocess, sensitivity shift value determination process 112 continues with task 138 so that the outcome of the real-time calculation subprocess, i.e., one or more sensitivity shift values 84, may be stored in memory element 78 of FIG. 3 of MEMS device package 50.

At query task 148, when a determination is made that the predetermined register value is not equal to “10,” it therefore is equal to “11” by process of elimination. Accordingly, a negative outcome of query task 148 causes process 112 to continue with a task 152. At task 152, sensitivity shift value 84, M, is left unprogrammed. As such following task 152, sensitivity shift value determination process 112 exits. Accordingly, sensitivity shift value 84 determined at any of tasks 136, 146, and 150 is determined prior to MEMS device package being board mounted in a customer application. As such, sensitivity shift value 84 is therefore governed by the performance of gyroscope die 24, and particularly, gyroscope circuit 60 of FIG. 3 of gyroscope die 24.

In an embodiment, a predetermined register value of “11” is left unprogrammed so that sensitivity shift value 84 can be programmed following board mount in a customer application. Accordingly, operations associated with process 112 may be adapted for execution following board mount in a customer-based test environment. By way of example, tasks 126, 128, 130, and 132 may be performed prior to board mount of MEMS device package 50 with magnetometer die 22 being subjected to a one Gauss magnetic field and a two Gauss magnetic field to produce MAG_{PRE-ACTIVE@1G} and MAG_{PRE-ACTIVE@2G}. Tasks 126, 128, 130, and 132 could be repeated following board mount of MEMS device package 50 again with magnetometer die 22 being subjected to a one Gauss magnetic field and a two Gauss magnetic field to produce MAG_{posT-ACTIVE@1G} and MAG_{POST-ACTIVE@2G}. The subscripted terminology used above indicates pre- or post-board mount with gyroscope die 24 in the active mode (variable current), and magnetometer die 24 being subjected to either one Gauss (1G) or two Gauss (2G).

Accordingly, sensitivity shift value 84, M, may be solved in a customer-based test environment as follows:

M≈(MAG_{PRE-ACTIVE@1G}−MAG_{PRE-ACTIVE@2G})/(MAG_{POST-ACTIVE@1G}−MAG_{POST-ACTIVE@2G})

One or more sensitivity shift values 84, M, determined in the customer-based test environment thus takes into account both the performance of gyroscope die 24 along with the stress conditions imposed on magnetometer die 22 following board mount. The one or more sensitivity shift values 84 may subsequently be stored in memory element 78 of FIG. 3.

The above presented sensitivity shift value determination process 112 provides a description for determining sensitivity shift value 84 for a single detection axis of magnetometer die 22. In some embodiments, magnetometer die 22 may be capable of sensing magnetic fields along more than one axis, and outputting corresponding magnetometer output signals for each axis. With such a configuration, detection tasks 128 and 132 may be performed for each sense axis of magnetometer die 22 in order to compute multiple sensitivity shift values 84, where each sensitivity shift value 84 is associated with its particular sense axis for magnetometer die 22. Accordingly, trim parameters 72 of FIG. 3 for sensitivity shift value 84 may include multiple sensitivity shift values 84, represented by X, Y, Z in FIG. 3.

FIG. 8 shows a flowchart of a real-time calculation subprocess 160 of executed in connection with task 150 of sensitivity shift value determination process 112 of FIG. 7. Subprocess 160 may be executed during factory-based testing within test environment 106 of FIG. 5. In accordance with real-time calculation subprocess 160, sensitivity shift values 84 will be determined and stored in memory element 78. However, the sensitivity shift values 84 will be governed by performance of gyroscope die 24, sensitivity shift values 84 will change based on variable current 86 of FIG. 3, and the sensitivity shift values 84 will change as the variable current 86 changes.

Real-time calculation subprocess 160 begins with a task 162. At task 162, magnetometer die 22 is activated, i.e., placed in operational state 94, and gyroscope die 24 is deactivated, i.e., placed in non-operational state 96 (0-1 in state diagram 90 shown in FIG. 4).

A task 164 is performed in connection with task 162. At task 164, magnetometer output signal 30 from magnetometer die 22 is detected at test equipment 108. As shown in task block 164, magnetometer output signal 30 is referred to as MAG_{GYRO-OFF} to emphasize that gyroscope die 24 is in non-operational state 96. Accordingly, magnetometer output signal 30 will not have signal error 70 imposed on it.

Subprocess 160 continues with a task 166. At task 166, magnetometer die 22 is again activated, i.e., placed in operational state 94, and gyroscope die 24 is also activated, i.e., placed in operational state 94 (1-1 in state diagram 90 shown in FIG. 4). Additionally, gyroscope die 24 is placed in active mode 100 of FIG. 4 such that gyroscope die 24 draws variable electric current 84. Under these conditions, variable electric current 84 produces magnetic field 38 of FIG. 1 which may be imposed on magnetometer output signal 30.

Accordingly, a task 168 is performed in connection with task 166. At task 168 magnetometer output signal 30 is again detected, i.e., read, at test equipment 108. However, magnetometer output signal 30 may include signal error 70 caused by magnetic field 38, in the form of sensitivity shift component 76 of FIG. 3. Sensitivity shift component 76 may be responsive to the variability of, or change in, variable current 84 when gyroscope die 24 is in active mode 100 of FIG. 4. Accordingly, as shown in task block 168, magnetometer output signal 30 is referred to as MAG_{GYRO-ACTIVE} to emphasize that gyroscope die 24 is in operational state 94 of FIG. 4, and particularly in active mode 100. Magnetometer output signal 30, i.e., MAG_{GYRO-ACTIVE}, is saved at task 168 as “S1.”

Real-time calculation subprocess 160 continues with a task 170. At task 170, test equipment 108 monitors magnetometer output signal 30, MAG_{GYRo-ACTIVE}, to determine whether it is changing in response to variable current 86.

A task 172 is performed in connection with task 170. At task 172, magnetometer output signal 30 is again detected, i.e., read, at test equipment 108. Magnetometer output signal 30, i.e., MAG_{GYRO-ACTIVE}, is saved at task 172 as “S2.”

Real-time calculation subprocess 160 continues with a query task 174. At query task 174, a determination is made as to whether a difference between magnetometer output signals 30, i.e., S1-S2, is greater than zero. When S1-S2 is greater than zero, subprocess 160 advances to task 176. At task 176, sensitivity shift value 84, M, is increased by one, where one is one step. Step size of the step may be defined by some predetermined resolution. Following task 176, process control loops back to task 168 to take additional readings of magnetometer signal 30. However, at query task 174, when a determination is made that the difference between magnetometer output signals 30, i.e., S1-S2, is not greater than zero, execution of subprocess 160 continues with a query task 178.

At query task 178, a determination is made as to whether a difference between magnetometer output signals 30, i.e., S1-S2, is less than zero. When S1-S2 is less than zero, subprocess 160 advances to task 180. At task 180, sensitivity shift value 84 is decreased by one, where one is one step defined by some predetermined resolution. Following task 180, process control again loops back to task 168 to take additional readings of magnetometer signal 30. However, at query task 178, when a determination is made that the difference between magnetometer output signals 30, i.e., S1-S2, is not less than zero, execution of subprocess 160 ends. Accordingly, execution of real-time calculation subprocess 160 continues until magnetometer output signals 30 read at tasks 168 and 172 are equal, i.e. S1=S2. Once S1 and S2 are equal, the resulting sensitivity shift value 84 is stored in memory element 78 for magnetometer die 22 in accordance with task 138 of FIG. 7 of sensitivity shift value determination process 112.

Through the execution of sensitivity shift value determination process 112 of FIG. 7 and real-time calculation subprocess 160, sensitivity shift value 84 can be one, can be an average of multiple devices, can be real time changing based on a digital logic stage machine. Additionally or alternatively, sensitivity shift value 84 can be left unprogrammed for an end user to program, or sensitivity shift value 84 can be programmed after board mount of MEMS device package 50.

FIG. 9 shows a flowchart of a magnetometer signal error compensation process 182 in accordance with an embodiment. Magnetometer signal error compensation process 182 provides exemplary methodology for compensating for signal error 70 of FIG. 3 imposed on magnetometer output signal 30 of FIG. 1 when gyroscope die 24 is in operational state 94 of FIG. 4 and in either standby mode 98 of FIG. 4 or active mode 100 of FIG. 4. Accordingly, compensation process 182 may be implemented as gyro error compensation algorithm 68 of FIG. 3, and as an adjunct to the conventional compensation algorithm 66 of FIG. 3.

In an embodiment, magnetometer signal error compensation process 182 is implemented within and executed at magnetometer circuit 56 of FIG. 3 of magnetometer die 22 of FIG. 3. Typically, MEMS sensor packages have compensation algorithms applied at the application level, i.e., end user logic. A problem with this conventional approach to compensation is that an error signal present in the raw analog sensor signal typically gets larger as it is processed and as it is eventually digitized. Therefore, the end user logic may be more complex, the memory requirements for such end user logic are undesirably high, and the resulting compensated signal may still contain some signal error. By placing magnetometer signal error compensation process 182 on the silicon of MEMS device package 50 of FIG. 3 at the digital input of magnetometer circuit 56, there may be significantly lower memory requirements for compensation. Additionally, the front end compensation methodology can result in a cleaner signal output, i.e., compensated magnetometer output signal 34 of FIG. 3, thereby achieving improvements in signal accuracy. Furthermore, such compensation methodology within magnetometer circuit 56 enables a customer to use multiple stimulus sensing MEMS device package 50 as a standalone unit without an additional requirement for end user logic, resulting in greater simplicity and cost savings to the customer.

Compensation process 182 begins with a query task 184. At query task 184, a determination is made as to whether magnetometer die 22 is in operational state 94 of FIG. 4. When magnetometer die 22 is not currently in operational state 94, process control proceeds to a query task 186.

Query task 186 determines whether execution of magnetometer signal error compensation process 182 is to continue. Of course, it should be apparent that when MEMS device package 50 is installed in an end user device, monitoring of the operational states of the individual sensors within package 50 is likely to be continuous. Accordingly, when execution of process 182 is to continue, program control loops back to query task 184. However, if at query task 186, the execution of magnetometer signal error compensation process 182 is to be discontinued, process 182 ends.

Now when a determination is made at query task 184 that magnetometer die 22 is in operational state 94, compensation process 182 continues with a query task 188. At query task 188, a determination is made as to whether gyroscope die 24 of FIG. 3 is also in operational state 94. Thus, the combination of query tasks 184 and 188 is looking for the condition in which both magnetometer die 22 and gyroscope die 24 are in operational state 94 (1-1 in state diagram 90 of FIG. 4). When gyroscope die 24 is not in operational state 94, i.e. it is in non-operational state 96, compensation process 182 continues with a task 190. At task 190, conventional compensation is performed on magnetometer output signal 30 in accordance with compensation algorithm 66, such as, trim offset, gain adjust, temperature offset, temperature sensitivity, and so forth, to produce a compensated magnetometer signal. However, trim parameters 72 corresponding to either of gyroscope-based offset or sensitivity shift components 74, 76 of signal error 70 of FIG. 3 are not applied to magnetometer output signal 30. That is, task 190 abstains from applying trim parameters 72. Following execution of task 190, process control advances to query task 186 to determine whether monitoring is to continue, as discussed above.

Now returning to query task 188, when a determination is made that gyroscope die 24 is in operational state 94, a query task 192 is performed. At query task 192, a determination is made as to whether gyroscope die 24 is in standby mode 98 of FIG. 4. When a determination is made at query task 192 that gyroscope die 24 is in standby mode 98, compensation process 182 continues with a task 194 to perform compensation in accordance with standby mode 98. Alternatively, when a determination is made at query task 192 that gyroscope die 24 is not in standby mode 98, i.e. it is in active mode 100 of FIG. 4, compensation process 182 continues with a task 196 to perform compensation in accordance with active mode 100.

Referring to FIG. 3 in connection with task 194, when gyroscope die 24 is in standby mode 98, task 194 is executed to apply trim parameters 72, and particularly gyro-offset trim value(s) 80 stored in memory element 78, to magnetometer output signal 30 to compensate for the gyroscope-based offset component 74 of signal error 70. Additionally, in some embodiments, sensitivity shift value 84, M, may be set to one, indicating that sensitivity shift component 76 is not a significant contributor to signal error 70. In response to task 194, compensation process 182 continues with a task 198 (discussed below).

With continued reference to FIG. 3 in connection with task 196, when gyroscope die 24 is in active mode 100, task 196 is executed to apply trim parameters 72, and particularly sensitivity shift value(s) 84 stored in memory element 78, to magnetometer output signal 30 to compensate for the sensitivity shift component 76 of signal error 70. In some embodiments, sensitivity shift value(s) 84 may be those computed following board mount of MEMS device package 50 so as to account for both sensitivity shift component 76 of signal error 70 (i.e., gyroscope die 24 performance) as well as the stress conditions imposed on magnetometer die 22 in response to board mount. Additionally, in some embodiments, gyroscope-based offset trim value 80 may be set to zero, indicating that gyroscope-based offset component 74 is not a significant contributor to signal error 70. Like task 196, compensation process 182 continues with task 198.

At task 198, trim parameters 72 determined from the execution of either of tasks 194 or 196 are applied to obtain compensated magnetometer output signal 34 of FIG. 3.

An exemplary trim equation 200 provided at task 198 reveals that an outcome 202, labeled REGULAR COMPENSSATION, of conventional compensation algorithm 66 is multiplied by sensitivity shift value 84, M, and gyroscope-based offset trim value 80 is added to outcome 202 of conventional compensation algorithm 66 to obtain compensated magnetometer output signal 34. In an embodiment, trim equation 158 may be derived as follows:

For X Axis:

$$\begin{matrix}trim\_out1 \_x = C 1 {x}^{*} ( {MAG}_{RAW ( x )} + C 0 x ) & ( 1 ) \\ trim\_out2 \_x = D 1 {x}^{*} T & ( 2 ) \\ trim\_out3 \_x = E 1 {{x}^{*} ( {MAG}_{RAW ( x )} + C 0 x )}^{*} T & ( 3 ) \\ trim\_out4 \_x = Gyroscope \text{-} based Offset Trim Value \\ \begin{matrix}{MAG}_{COM ( X )} = M ( trim\_out1 \_x + trim\_out2 \_x + trim\_out3 \_x ) - \\ trim\_out4 \_x \\ = M ( REGULAR COMPENSATION ) + \\ TRIM VALUE\end{matrix} & ( 4 )\end{matrix}$$

### DEFINITIONS

MAG_{RAW(x)}, MAG_{RAW(Y)}, MAG_{RAW(Z)}=Raw magnetometer output signal 30, for X axis, Y axis, and Z axis
C0x, C0y, C0z=X axis, Y axis, and Z axis offset at 25° C.
C1x, C1y, C1z=First order Sensitivity coefficient for X axis, Y axis, and Z axis, respectively
D1x, D1y, D1z=First order Temperature Offset coefficient (TCO) for X axis, Y axis, and Z axis, respectively
E1x, E1y, E1z=Temperature Sensitivity coefficient (TCS1) for X axis, Y axis, and Z axis, respectively

In an exemplary embodiment, the equations corresponding to trim_out1_x, trim_out2_x, and trim_out3_x pertain to applying trim coefficients for sensitivity, temperature offset, and temperature sensitivity to magnetometer output signal 30 relative to the X axis in accordance with the conventional compensation algorithm 66. In a multiple sense axis magnetometer die 22, similar trim equations may be derived for Y axis and Z axis, using the definitions provided above. Of course, those skilled in the art will recognize that a conventional compensation algorithm may have more or less trim coefficients than those shown herein, and the trim coefficients may include different calibration/compensation parameters.

Sensitivity shift value 84, M, is applied to outcome 202 of the regular, or conventional, compensation. Therefore, sensitivity shift value 84 is applied to magnetometer output signal 30 by multiplication, to obtain compensated magnetometer output signal 34, MAG_{COM}. Gyroscope-based offset trim value 80 is applied to magnetometer output signal 30 by addition to obtain compensated magnetometer signal 34, MAG_{COM}.

In the exemplary embodiment, when sensitivity shift value 84 is set to 1 at task 194, only gyroscope-based offset trim value 80 added to outcome 202 of regular compensation within trim equation 200 influences compensated magnetometer output signal 34. That is, there may be little or no sensitivity shift component 76 in signal error 70 for which compensation is needed. Alternatively, in the exemplary embodiment, when gyroscope-based offset trim value 80 is set to 0 at task 196, only sensitivity shift value 84 multiplied with outcome 202 of regular compensation within trim equation 200 is used to produce compensated magnetometer output signal 34. That is, there may be little or no gyroscope-based offset component 74 in signal error 70 for which compensation is needed. In other embodiments, however, it is possible that both sensitivity shift component 76 and gyroscope-based offset component 74 yield in signal error 70. In such an instance, sensitivity shift value 84, M, may be set to something other than 1 and gyroscope-based offset trim value 80 may be set to something other than 0 to obtain compensated magnetometer output signal 34.

Thus, a multiple stimulus sensing MEMS device package that includes a magnetometer and another sensor, and a method of compensating for signal error on an output signal of the magnetometer resulting from current draw by the other sensor have been described. In a device that includes a magnetometer and a second sensor, an embodiment of a method of compensating for signal error on an output signal of the magnetometer comprises detecting whether the second sensor is in an operational state in which the second sensor is drawing an electric current, and when the second sensor is in the operational state, applying a trim parameter to the output signal, the trim parameter canceling at least a portion of the signal error on the output signal, wherein the signal error is generated at the magnetometer in response to the electric current drawn by the second sensor in the operational state.

An embodiment of device comprises a magnetometer adapted to produce an output signal indicative of a sensed magnetic field, a second sensor, and a processing unit connected to each of the magnetometer and the second sensor. The processing unit is configured to perform operations comprising detecting whether the second sensor is in an operational state in which the second sensor is drawing an electric current, and when the second sensor is in the operational state, applying a trim parameter to the output signal, the trim parameter canceling at least a portion of a signal error on the output signal, wherein the signal error is generated at the magnetometer in response to the electric current drawn by the second sensor in the operational state.

Thus, embodiments entail a multiple stimulus sensing MEMS device package that includes both a magnetometer and another sensor, such as a gyroscope, and methodology for compensating for signal error imposed on the magnetometer output signal when the other sensor is in an operational state. The compensation methodology is implemented in an analog front end and digital processing application specific integrated circuit (ASIC) for the MEMS device package to improve signal accuracy, to reduce memory requirements, and to provide an error compensated signal to an end user without the need for implementation of end user logic.

While the principles of the inventive subject matter have been described above in connection with a specific apparatus and method, it is to be clearly understood that this description is made only by way of example and not as a limitation on the scope of the inventive subject matter. Further, the phraseology or terminology employed herein is for the purpose of description and not of limitation.

The foregoing description of specific embodiments reveals the general nature of the inventive subject matter sufficiently so that others can, by applying current knowledge, readily modify and/or adapt it for various applications without departing from the general concept. Therefore, such adaptations and modifications are within the meaning and range of equivalents of the disclosed embodiments. The inventive subject matter embraces all such alternatives, modifications, equivalents, and variations as fall within the spirit and broad scope of the appended claims.

What is claimed is:

1. In a device that includes a magnetometer and a second sensor, a method of compensating for signal error on an output signal of said magnetometer comprising:
detecting whether said second sensor is in an operational state in which said second sensor is drawing an electric current; and
when said second sensor is in said operational state, applying a trim parameter to said output signal, said trim parameter canceling at least a portion of said signal error on said output signal, wherein said signal error is generated at said magnetometer in response to said electric current drawn by said second sensor in said operational state.

2. A method as claimed in claim 1 wherein:
said detecting operation includes determining whether said electric current is a substantially non-variable electric current; and
when said electric current is said substantially non-variable electric current, said applying operation applies an offset trim value of said trim parameter to said output signal, said offset trim value being associated with said non-variable electric current.

3. A method as claimed in claim 2 wherein said offset trim value is a function of said non-variable electric current and a fixed distance between said magnetometer and a sensor circuit associated with said second sensor.

4. A method as claimed in claim 2 wherein said applying operation comprises determining, by addition, a summation of said offset trim value and said output signal to obtain a compensated magnetometer output signal.

5. A method as claimed in claim 1 wherein:
said detecting operation includes determining whether said electric current is a variable electric current; and
when said electric current is said variable electric current, said applying operation applies a sensitivity shift value of said trim parameter to said output signal, said sensitivity shift value being associated with said variable electric current.

6. A method as claimed in claim 5 further comprising determining said sensitivity shift value as a function of said variable current and a stress condition imposed on said magnetometer.

7. A method as claimed in claim 5 wherein said sensitivity shift value characterizes a change in a sensitivity of said magnetometer to detecting a magnetic field, said change in said sensitivity resulting from said variable current.

8. A method as claimed in claim 5 wherein said applying operation includes determining, by multiplication, a product of said sensitivity shift value and said output signal to obtain a compensated magnetometer output signal.

9. A method as claimed in claim 1 wherein said second sensor comprises a gyroscope, and:
said detecting operation includes determining whether said operational state of said gyroscope is one of a standby mode and an active mode; and
said applying operation includes applying an offset trim value of said trim parameter to said output signal when said gyroscope is in said standby mode and applying a sensitivity shift value of said trim parameter to said output signal when said gyroscope is in said active mode.

10. A method as claimed in claim 1 wherein said output signal is an analog output signal from said magnetometer, and said applying operation applies said trim parameter to said analog output signal.

11. A method as claimed in claim 1 wherein when said detecting operation detects that said second sensor is in a nonoperational state in which said second sensor is not drawing said electric current, abstaining from performing said applying operation.

12. A method as claimed in claim 1 further comprising:
prior to said detecting operation, generating said trim parameter based on said electric current drawn by said second sensor when said second sensor is in said operational state; and
storing said trim parameter in a memory element associated with said magnetometer.

13. A device comprising:
a magnetometer adapted to produce an analog output signal indicative of a sensed magnetic field;
a second sensor; and
a processing unit connected to each of said magnetometer and said second sensor, said processing unit being configured to perform operations comprising:
detecting whether said second sensor is in an operational state in which said second sensor is drawing an electric current; and
when said second sensor is in said operational state, applying a trim parameter to said analog output signal, said trim parameter canceling at least a portion of a signal error on said output signal, wherein said signal error is generated at said magnetometer in response to said electric current drawn by said second sensor in said operational state.

14. A device as claimed in claim 13 wherein said second sensor includes a sensor circuit, said sensor circuit being positioned a fixed spatial distance away from said magnetometer, and said trim parameter is a function of said electric current and said fixed spatial distance.

15. A device as claimed in claim 13 wherein said second sensor comprises a gyroscope.

16. A device as claimed in claim 13 further comprising a memory element associated with said magnetometer, said memory element having said trim parameter stored therein.

17. A device as claimed in claim 16 wherein said trim parameter comprises an offset trim value associated with a non-variable electric current in said memory element, and when said electric current is said non-variable electric current, said processing unit determines, by addition, a summation of said offset trim value and said output signal to obtain a compensated magnetometer output signal.

18. A device as claimed in claim 16 wherein said trim parameter comprises a sensitivity shift value associated with a variable electric current in said memory element, and when said electric current is said variable electric current, said processing unit determines, by multiplication, a product of said sensitivity shift value and said output signal, said product being a compensated magnetometer output signal.

19. In a device that includes a magnetometer and a second sensor, a method of compensating for signal error on an output signal of said magnetometer comprising:
generating a trim parameter based on an electric current draw of said second sensor;
storing said trim parameter in a memory element associated with said magnetometer;
detecting whether said second sensor is in an operational state in which said second sensor is drawing said electric current;
when said detecting operation detects that said second sensor is in said operational state, selecting said trim parameter from said memory element and applying said trim parameter to said output signal, said trim parameter canceling at least a portion of said signal error on said output signal, wherein said signal error is generated at said magnetometer in response to said electric current drawn by said second sensor in said operational state; and
when said detecting operation detects that said second sensor is in a nonoperational state in which said second sensor is not drawing said electric current, abstaining from applying said trim parameter to said output signal.

20. A method as claimed in claim 19 wherein:
said detecting operation includes determining whether said electric current is a substantially non-variable electric current or a variable electric current;
when said electric current is said substantially non-variable electric current, said applying operation determines, by addition, a summation of an offset trim value of said trim parameter and said output signal to obtain a compensated magnetometer output signal, wherein said offset trim value is associated with said non-variable electric current; and
when said electric current is said variable electric current, said applying operation determines, by multiplication, a product of a sensitivity shift value of said trim parameter and said output signal to obtain said compensated magnetometer output signal, wherein said sensitivity shift value is associated with said variable electric current.
